(19) United States
(12) Patent Application Publication
(10) Pub. No.: US 2010/0084685 A1
(43) Pub. Date: Apr. 8, 2010

(54) SEMICONDUCTOR DEVICE AND MANUFACTURING METHOD THEREOF

(76) Inventors: Hiroshi ITOKAWA, Yokohama-shi (JP); Takashi Fukushima, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/563,334

(22) Filed: Sep. 21, 2009

(30) Foreign Application Priority Data
Oct. 7, 2008 (JP) 2008-260798

(51) Int. Cl. H01L 29/786; H01L 21/336

(52) U.S. Cl. 257/192; 438/285; 257/E21.411; 257/E29.273

(57) ABSTRACT

A semiconductor device includes an SiGe film formed on part of a semiconductor substrate and including a channel region and at least part of source/drain extension regions between which the channel region is positioned, source/drain contact regions formed in a surface area of the semiconductor substrate and brought into contact with the pair of source/drain extension regions, a gate structure having a gate insulation film formed on the SiGe film and a gate electrode formed on the gate insulation film, first sidewall films formed on the SiGe film along side surfaces of the gate structure, second sidewall films formed on the SiGe film along the first sidewall films, third sidewall films formed on the source/drain contact regions along side surfaces of the SiGe film and the second sidewall films, and first silicide films formed on the source/drain contact regions.

### CROSS-REFERENCE TO RELATED APPLICATIONS

This application is based upon and claims the benefit of priority from prior Japanese Patent Application No. 2008-260798, filed Oct. 7, 2008, the entire contents of which are incorporated herein by reference.

### BACKGROUND OF THE INVENTION

1. Field of the Invention

The present invention relates to a semiconductor device and a manufacturing method thereof.

2. Description of the Related Art

Recently, the design of semiconductor devices is becoming finer, and the development of ultra-small ultra-high-speed field-effect transistors (FETs) is being worked on. In an FET of this type, a channel region immediately below a gate electrode is given a far smaller area than in a conventional FET. For this reason, the mobility of electrons or holes that travel in the channel region is largely affected by stress applied to the channel region. A technology has been suggested, with which the operating speed of the FET can be improved by optimizing the stress applied to the channel region.

To improve the operating speed, a technology of incorporating an SiGe film in the channel region has been suggested (see Japanese Patent No. 2528537, for example). The mobility of holes is increased by forming an SiGe film in the channel region, which improves the performance of the FET. In the conventional technologies, however, the position of the SiGe film is not always appropriately determined. It therefore has been difficult to achieve a reliable semiconductor device that has excellent properties.

### BRIEF SUMMARY OF THE INVENTION

According to a first aspect of the present invention, there is provided a semiconductor device comprising: an SiGe film formed on part of a semiconductor substrate and including a channel region and at least part of a pair of source/drain extension regions between which the channel region is positioned; a pair of source/drain contact regions formed in a surface area of the semiconductor substrate and brought into contact with the pair of source/drain extension regions; a gate structure having a gate insulation film formed on the SiGe film and a gate electrode formed on the gate insulation film; first sidewall films formed on the SiGe film along side surfaces of the gate structure; second sidewall films formed on the SiGe film along the first sidewall films; third sidewall films formed on the source/drain contact regions along side surfaces of the SiGe film and the second sidewall films; and a pair of first silicide films formed on the pair of source/drain contact regions.

According to a second aspect of the present invention, there is provided a semiconductor device manufacturing method comprising: forming an SiGe film on a semiconductor substrate; forming, on the SiGe film, a gate structure including a gate insulation film and a gate electrode on the gate insulation film; forming first sidewall films on the SiGe film along side surfaces of the gate structure; forming source/drain extension regions by introducing impurities at least into the SiGe film using the gate structure and the first sidewall films as a mask; forming second sidewall films on the SiGe film along the first sidewall films; removing the SiGe film other than a first portion thereof covered by the gate structure, the first sidewall films and the second sidewall films; forming source/drain contact regions by introducing impurities into the semiconductor substrate using the gate structure, the first sidewall films and the second sidewall films as a mask; forming third sidewall films on the source/drain contact regions along side surfaces of the first portion of the SiGe film and the second sidewall films; and forming first silicide films on the source/drain contact regions.

### BRIEF DESCRIPTION OF THE SEVERAL VIEWS OF THE DRAWING

FIG. 1 is a schematic diagram showing a cross section of a structure of a semiconductor device according to a comparative example of an embodiment of the present invention.

FIG. 2 is a schematic diagram showing a cross section of a structure of a semiconductor device according to the embodiment of the present invention.

FIG. 3 is a schematic diagram showing a cross section of the semiconductor device obtained at a step of the production process according to the embodiment of the present invention.

FIG. 4 is a schematic diagram showing a cross section of the semiconductor device obtained at another step of the production process according to the embodiment of the present invention.

FIG. 5 is a schematic diagram showing a cross section of the semiconductor device obtained at still another step of the production process according to the embodiment of the present invention.

FIG. 6 is a schematic diagram showing a cross section of the semiconductor device obtained at still another step of the production process according to the embodiment of the present invention.

FIG. 7 is a schematic diagram showing a cross section of the semiconductor device obtained at still another step of the production process according to the embodiment of the present invention.

### DETAILED DESCRIPTION OF THE INVENTION

An embodiment of the present invention will be explained in detail below, with reference to the attached drawings.

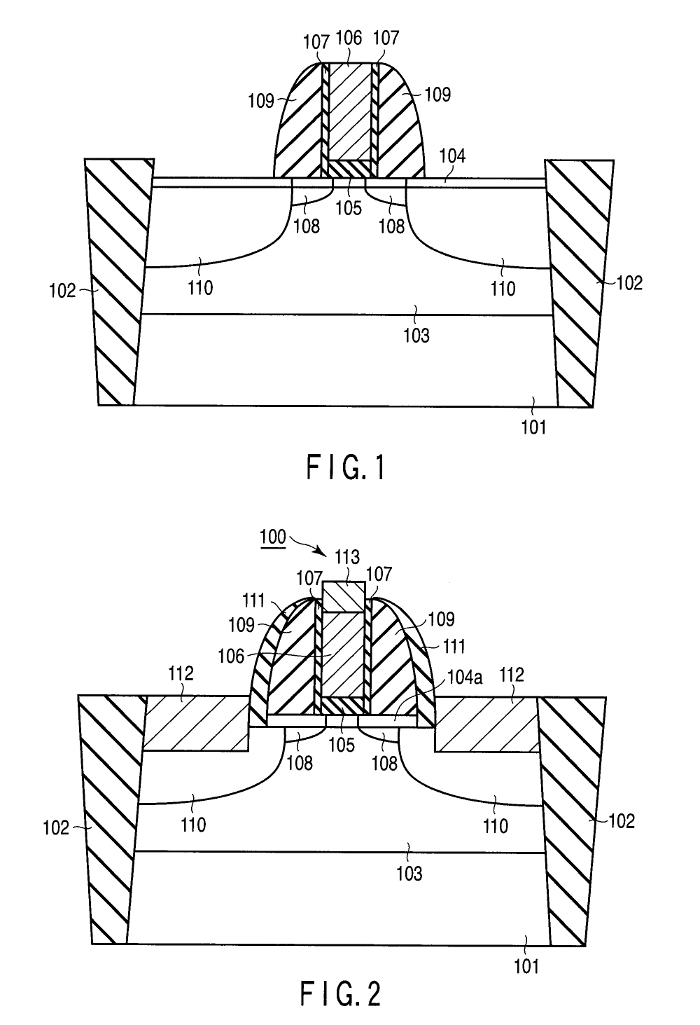

Before discussing the present embodiment, a comparative example of the embodiment will be first explained. FIG. 1 is a schematic diagram showing a cross section of a basic structure of the comparative example.

As illustrated in FIG. 1, an isolation insulation film 102 is formed in a semiconductor substrate 101 having a p-type well region 103. An SiGe film 104 is deposited on the semiconductor substrate 101 to have a channel region and source/drain extension regions 108 therein. Furthermore, a pair of source/drain contact regions 110 are formed in the surface area of the semiconductor substrate 101 in such a manner as to be in contact with the source/drain extension regions 108.

A gate structure having a gate insulation film 105 and a gate electrode 106 deposited on the gate insulation film 105 is fabricated on the SiGe film 104. Moreover, first sidewall films (offset spacers) 107 are formed along the sidewall of the gate structure on the SiGe film 104. Second sidewall films 109 are formed along the first sidewall films 107 on the SiGe film 104.

In the above comparative example, the SiGe film 104 is exposed at the surface. Because of this arrangement, the SiGe film 104 is etched off when the structure is cleaned with a chemical solution such as HF solution, alkaline solution (e.g., NH₄OH and choline) and hydrogen peroxide solution in advance of the deposition of silicide films on the source/drain contact regions 110 and the gate electrode 106. Then, the peeling of the sidewall film occurs Because of the side etching and the surface morphology becomes rough, which results in abnormal growth of the silicide.

FIG. 2 is a schematic diagram showing a cross section of a basic structure of a semiconductor device (p-channel FET) according to the present embodiment.

As illustrated in FIG. 2, an isolation insulation film (isolation insulation region) 102 is formed in a semiconductor substrate (substrate mainly containing silicon, such as a silicon substrate) 101 having a p-type well region 103. An SiGe film 104a approximately 2 to 10 nm thick is formed on the semiconductor substrate 101 in such a manner as to include a channel region and at least part of a pair of source/drain extension regions 108 that sandwich the channel region therebetween. A pair of source/drain contact regions 110 are formed in the surface area of the semiconductor substrate 101 in such a manner as to be in contact with the source/drain extension regions 108.

A gate structure having a gate insulation film 105 and a gate electrode 106 formed on the gate insulation film 105 is fabricated on the SiGe film 104a. The gate insulation film 105 is an insulation film (silicon nitride film or high-dielectric film) having a relative dielectric constant (permittivity) higher than 3.9 (which is the relative dielectric constant of the silicon oxide film). The gate electrode 106 is formed of poly silicon. First sidewall films 107 are formed along the side surface of the gate structure on the SiGe film 104 in such a manner as to have a width of approximately 2 to 5 nm. The first sidewall films 107 are silicon oxide films, having a dielectric constant lower than that of the gate insulation film 105. Further, second sidewall films 109 are formed along the first sidewall films 107 on the SiGe film 104. These second sidewall films 109 are silicon nitride films. Third sidewall films 111 are formed along the second sidewall films 109 and the side surface of the SiGe film 104a on the source/drain contact regions 110. The third sidewall films 111 are silicon oxide films.

A pair of silicide films 112 are formed on the source/drain contact regions 110. Each of the third sidewall films 111 is partially sandwiched between the silicide films 112 and the SiGe film 104a. A silicide film 113 is formed in the surface area of the gate electrode 106. The silicide films 112 and the silicide film 113 are nickel monosilicide (NiSi) films. An NiPt silicide film may be adopted for the silicide films. The silicide films 112 and the silicide film 113 do not contain Ge.

According to the present embodiment, the SiGe film 104a is arranged to be sandwiched by the third sidewall films 111 and to have its side surfaces covered by the third sidewall films 111. With such an arrangement, the SiGe film 104a is protected against etching during the chemical solution cleaning before the formation of the silicide films. As a result, the silicide films can be prevented from abnormally growing Because of the peeled-off sidewall film caused by the side etching and the rough surface morphology.

In addition, because the silicide films are not formed on the SiGe film, the silicide is prevented from abnormally growing by a difference between the Ni—Ge reaction speed and the Ni—Si reaction speed. As a result, silicide films of excellent quality that do not contain Ge can be achieved.

Moreover, the first sidewall films 107 are formed of insulation films having a dielectric constant lower than that of the gate insulation film 105, on the side surfaces of the gate insulation film 105. This means that the electric field can be prevented from being concentrated at the end portions of the gate insulation film 105, which suppresses leakage current.

The basic manufacturing method of the semiconductor device according to the present embodiment will be explained with reference to FIGS. 2 to 7.

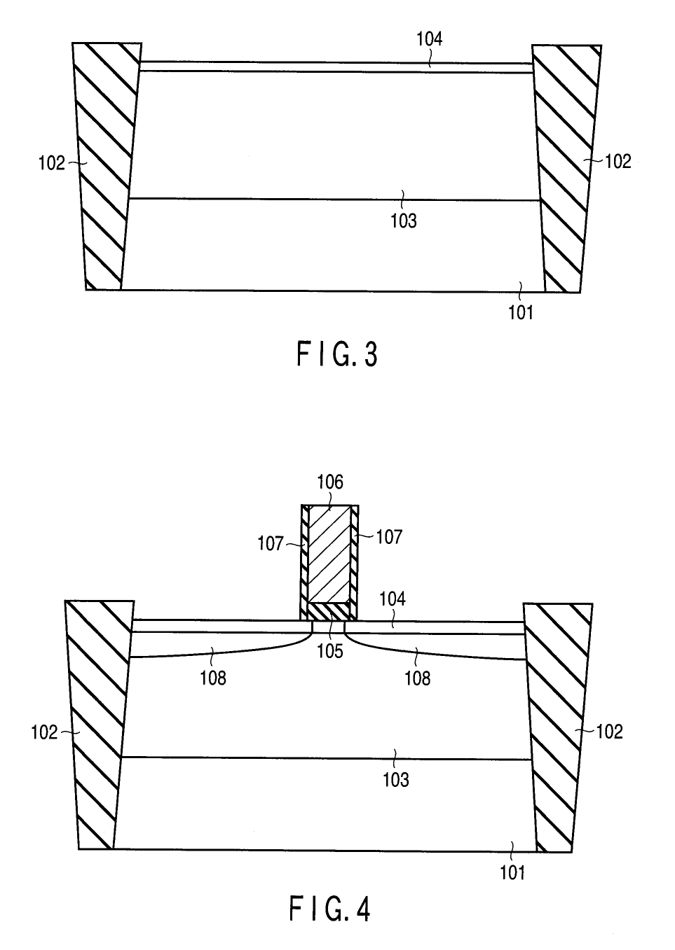

First, as illustrated in FIG. 3, a silicon oxide film is deposited in an isolation trench provided in the semiconductor substrate 101 to form the isolation insulation film 102. Next, a well region 103 is formed in the semiconductor substrate 101 that is surrounded by the isolation insulation film 102. Thereafter, the SiGe film 104 is formed approximately 2 to 10 nm (preferably, 5 to 7 nm) thick on the surface of the semiconductor substrate 101 surrounded by the isolation insulation film 102, through epitaxial growth. The Ge content of the SiGe film 104 should be 10 to 50 atom %, or more preferably around 30 atom %.

Next, as indicated in FIG. 4, an insulation film such as a silicon nitride film and a high-dielectric film is formed as the gate insulation film 105, and a poly silicon film is formed on the gate insulation film 105 to serve as the gate electrode film 106. Then, a gate structure including the gate insulation film 105 and the gate electrode 106 is fabricated by anisotropic etching such as reactive ion etching (RIE). Thereafter, a silicon oxide film is entirely deposited approximately 2 to 10 nm thick and anisotropic etching, such as RIE, is performed thereon so that first sidewall films 107 are formed, along the side surfaces of the gate structure on the SiGe film 104. The dielectric constant of the first sidewall films 107 is designed to be lower than that of the gate insulation film 105. Then, by using the gate structure and the first sidewall films 107 as a mask, impurities such as boron are ion-implanted into the SiGe film 104 and the semiconductor substrate 101. Furthermore, source/drain extension regions 108 are formed in the SiGe film 104 and the semiconductor substrate 101 by high-temperature short-time heat treatment such as rapid thermal annealing (RTA). Depending on the thickness of the SiGe film 104 and the impurity implantation condition, the source/drain extension regions 108 may be formed on the SiGe film 104, but not on the semiconductor substrate 101.

Next, as illustrated in FIG. 5, a silicon nitride film is entirely deposited, and anisotropic etching such as RIE is performed thereon so that the second sidewall films 109 are formed on the SiGe film 104 along the first sidewall films 107. Then, anisotropic etching such as RIE is performed by using the gate structure, the first sidewall films 107 and the second sidewall films 109 as a mask. As a result, all the SiGe film 104 other than the portion covered by the gate structure and the first and second sidewall films is removed, leaving only part of the SiGe film (first portion), 104a. The pattern of the SiGe film 104a may be formed by performing the RIE continuously from the deposition of the second sidewall film 109.

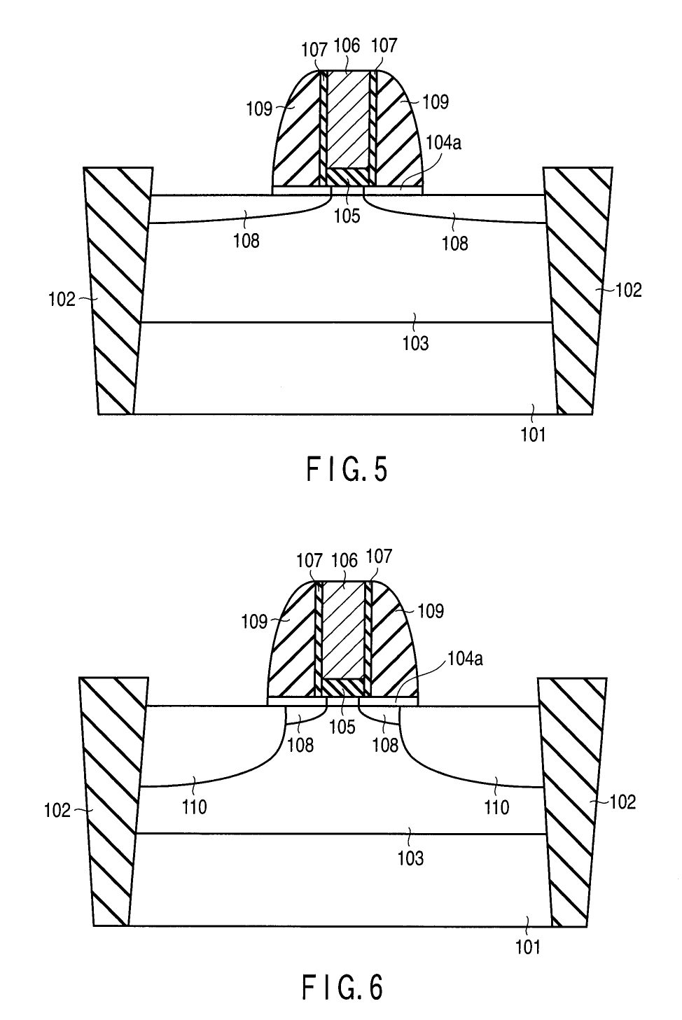

Next, as illustrated in FIG. 6, p-type impurity ions such as boron are implanted into the semiconductor substrate 101 by using the gate structure, the first sidewall films 107 and the second sidewall films 109 as a mask. Further, high-temperature short-time heat treatment such as RTA is performed to form source/drain contact regions 110 in the semiconductor substrate 101.

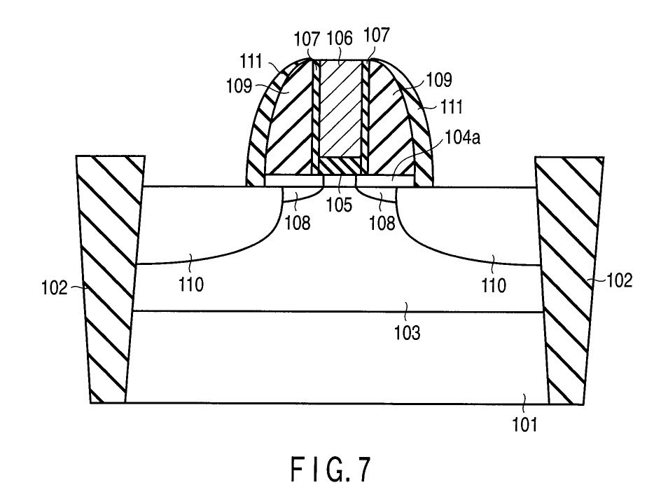

Thereafter, as illustrated in FIG. 7, a silicon oxide film is entirely deposited, onto which anisotropic etching such as RIE is performed. Third sidewall films 111 are thereby formed along the second sidewall films 109 and the side surfaces of the SiGe film 104a on the source/drain contact region 110.

Then, as illustrated in FIG. 2, nickel monosilicide films are formed as silicide films 112 on the surface of the source/drain contact region 110, and also a nickel monosilicide film is formed on the surface of the gate electrode 106 as a silicide film 113. More specifically, the procedure described below is followed.

First, as a pretreatment, cleaning is performed by use of a chemical solution such as an HF solution (HF concentration of 0.2 to 1%, for example), alkaline solution (e.g., NH₄OH and choline) and hydrogen peroxide solution. Then, a nickel film is entirely deposited. The silicide films 112 and the silicide film 113 are formed by heat treatment, in which the nickel film reacts with the silicon base material.

Finally, interconnect layers (not shown) are provided to complete the semiconductor device 100.

According to the above manufacturing method, the side surfaces of the SiGe film 104a are covered by the third sidewall films 111 so that the SiGe film 104a can be protected from being etched off at the cleaning process using a chemical solution. As a result, the sidewall film would not be peeled off by the side-etching of the SiGe film 104a, and the morphological roughness would not occur from the etching of the surface of the SiGe film 104. Furthermore, because reaction with Ge is prevented at the formation of the silicide films, silicide films of excellent quality can be reliably offered.

According to the above embodiment, carbon (C) may be added to the SiGe film 104. By adding C to the SiGe film, impurities are kept from diffusing into the interface between the SiGe film and the gate insulation film 105, and the crystalline state of the SiGe is improved (i.e., greater critical thickness and suppressed dislocation growth). This improves the electric characteristics. In addition, a thin Si film may be formed on the SiGe film 104 in order to improve the interface characteristics of the gate insulation film 105.

According to the above embodiment, a p-type MOSFET has been dealt with, but the same structure and method as the above can be applied to an n-type MOSFET.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
an SiGe film formed on part of a semiconductor substrate and including a channel region and at least part of a pair of source/drain extension regions between which the channel region is positioned;
a pair of source/drain contact regions formed in a surface area of the semiconductor substrate and brought into contact with the pair of source/drain extension regions;
a gate structure having a gate insulation film formed on the SiGe film and a gate electrode formed on the gate insulation film;
first sidewall films formed on the SiGe film along side surfaces of the gate structure;
second sidewall films formed on the SiGe film along the first sidewall films;
third sidewall films formed on the source/drain contact regions along side surfaces of the SiGe film and the second sidewall films; and
a pair of first silicide films formed on the pair of source/drain contact regions.

2. The device according to claim 1, wherein the third sidewall films include portions sandwiched between the SiGe film and the first silicide films.

3. The device according to claim 1, wherein the first silicide films do not contain Ge.

4. The device according to claim 1, wherein a Ge content of the SiGe film is 10 to 50 atom %.

5. The device according to claim 1, wherein a thickness of the SiGe film is 2 to 10 nm.

6. The device according to claim 1, wherein a second silicide film is formed in a surface area of the gate electrode.

7. The device according to claim 1, wherein a dielectric constant of the first sidewall films is lower than that of the gate insulation film.

8. A semiconductor device manufacturing method, comprising:
forming an SiGe film on a semiconductor substrate;
forming, on the SiGe film, a gate structure including a gate insulation film and a gate electrode on the gate insulation film;
forming first sidewall films on the SiGe film along side surfaces of the gate structure;
forming source/drain extension regions by introducing impurities at least into the SiGe film using the gate structure and the first sidewall films as a mask;
forming second sidewall films on the SiGe film along the first sidewall films;
removing the SiGe film other than a first portion thereof covered by the gate structure, the first sidewall films and the second sidewall films;
forming source/drain contact regions by introducing impurities into the semiconductor substrate using the gate structure, the first sidewall films and the second sidewall films as a mask;
forming third sidewall films on the source/drain contact regions along side surfaces of the first portion of the SiGe film and the second sidewall films; and
forming first silicide films on the source/drain contact regions.

9. The method according to claim 8, wherein the third sidewall films include portions sandwiched between the SiGe film and the first silicide films.

10. The method according to claim 8, wherein the first silicide films do not contain Ge.

11. The method according to claim 8, wherein a Ge content of the SiGe film is 10 to 50 atom %.

12. The method according to claim 8, further comprising cleaning surfaces of the source/drain contact regions with a chemical solution before forming the first silicide films.

13. The method according to claim 12, wherein the chemical solution is selected from an HF solution, alkaline solution and hydrogen peroxide solution.

14. The method according to claim 8, wherein a second silicide film is formed in a surface area of the gate electrode in forming the first silicide films.

15. The method according to claim 8, wherein a dielectric constant of the first sidewall films is lower than that of the gate insulation film.
